(19) United States
(12) Patent Application Publication
(10) Pub. No.: US 2022/0029505 A1
(43) Pub. Date: Jan. 27, 2022

(54) SYSTEMS AND METHODS FOR SENSING DISPLACEMENT OF AN ELECTROMECHANICAL TRANSDUCER

(71) Applicant: Cirrus Logic International Semiconductor Ltd., Edinburgh (GB)

(72) Inventors: Aleksey KHENKIN, Lago Vista, TX (US); Siddharth MARU, Austin, TX (US); Tejasvi DAS, Austin, TX (US); Emmanuel MARCHAIS, Dripping Springs, TX (US); Vadim KONRADI, Austin, TX (US); Viral PARIKH, Austin, TX (US); Jon D. HENDRIX, Wimberley, TX (US); Marco A. JANKO, Austin, TX (US)

(73) Assignee: Cirrus Logic International Semiconductor Ltd., Edinburgh (GB)

(21) Appl. No.: 17/497,110

(22) Filed: Oct. 8, 2021

Related U.S. Application Data
(63) Continuation-in-part of application No. 16/532,850, filed on Aug. 6, 2019.
(60) Provisional application No. 62/721,134, filed on Aug. 22, 2018.
(60) Provisional application No. 62/739,970, filed on Oct. 2, 2018.
(60) Provisional application No. 62/740,129, filed on Oct. 2, 2018.

(51) Int. Cl. H02K 7/065; G01D 5/243; H02K 41/03; G06F 3/01; G01R 27/26

(52) U.S. Cl. CPC H02K 7/065; G01D 5/243; G01R 27/2605; G06F 3/016; G01R 27/2611; H02K 41/031

(57) ABSTRACT

A system for detecting displacement of a movable member of an electromagnetic transducer having a magnetic coil-driven linear actuator with a static member and a movable mass mechanically coupled to the static member and having a back electromotive force present across terminals of a coil of the electromagnetic transducer is provided. The system may include a resistive-inductive-capacitive sensor comprising the coil, a driver configured to drive the resistive-inductive-capacitive sensor with a driving signal, a measurement circuit communicatively coupled to the resistive-inductive-capacitive sensor and configured to measure one or more of phase information and amplitude information associated with the resistive-inductive-capacitive sensor and based on the one or more of phase information and amplitude information, determine a displacement of movable mass, wherein the displacement of the movable mass causes a change in an impedance of the resistive-inductive-capacitive sensor.

### CROSS-REFERENCES AND RELATED APPLICATION

The present disclosure is a continuation-in-part of U.S. patent application Ser. No. 16/532,850, filed Aug. 6, 2019, which claims priority to U.S. Provisional Patent Application No. 62/721,134, filed Aug. 22, 2018, U.S. Provisional Patent Application No. 62/739,970, filed Oct. 2, 2018, and 62/740,129, filed Oct. 2, 2018, each of which is incorporated by reference herein in its entirety.

### FIELD OF DISCLOSURE

The present disclosure relates in general to methods, apparatuses, or implementations for haptic devices. Embodiments set forth herein may disclose improvements to how a displacement of a haptic actuator or other electromechanical load may be sensed.

### BACKGROUND

Vibro-haptic transducers, for example linear resonant actuators (LRAs), are widely used in portable devices such as mobile phones to generate vibrational feedback to a user. Vibro-haptic feedback in various forms creates different feelings of touch to a user's skin and may play increasing roles in human-machine interactions for modern devices.

An LRA may be modelled as a mass-spring electro-mechanical vibration system. When driven with appropriately designed or controlled driving signals, an LRA may generate certain desired forms of vibrations. For example, a sharp and clear-cut vibration pattern on a user's finger may be used to create a sensation that mimics a mechanical button click. This clear-cut vibration may then be used as a virtual switch to replace mechanical buttons.

FIG. 1 illustrates an example of a vibro-haptic system in a device 100. Device 100 may comprise a controller 101 configured to control a signal applied to an amplifier 102. Amplifier 102 may then drive a vibrational actuator (e.g., haptic transducer) 103 based on the signal. Controller 101 may be triggered by a trigger to output to the signal. The trigger may, for example, comprise a pressure or force sensor on a screen or virtual button of device 100.

Among the various forms of vibro-haptic feedback, tonal vibrations of sustained duration may play an important role to notify the user of the device of certain predefined events, such as incoming calls or messages, emergency alerts, and timer warnings, etc. In order to generate tonal vibration notifications efficiently, it may be desirable to operate the haptic actuator at its resonance frequency.

The resonance frequency f₀ of a haptic transducer may be approximately estimated as:

$${f}_{0} = \frac{1}{2 π \sqrt{C M}} \qquad ( 1 )$$

where C is the compliance of the spring system, and M is the equivalent moving mass, which may be determined based on both the actual moving part in the haptic transducer and the mass of the portable device holding the haptic transducer.

Due to sample-to-sample variations in individual haptic transducers, mobile device assembly variations, temporal component changes caused by aging, and use conditions such as various different strengths of a user gripping of the device, the vibration resonance of the haptic transducer may vary from time to time.

FIG. 2 illustrates an example of a linear resonant actuator (LRA) modelled as a linear system. LRAs are non-linear components that may behave differently depending on, for example, the voltage levels applied, the operating temperature, and the frequency of operation. However, these components may be modelled as linear components within certain conditions. In this example, the LRA is modelled as a third order system having electrical and mechanical elements. In particular, Re and Le are the DC resistance and coil inductance of the coil-magnet system, respectively; and Bl is the magnetic force factor of the coil. The driving amplifier outputs the voltage waveform V(t) with the output impedance Ro. The terminal voltage V_{T}(t) may be sensed across the terminals of the haptic transducer. The mass-spring system 201 moves with velocity u(t).

A haptic system may require precise control of movements of the haptic transducer. Such control may rely on the magnetic force factor Bl, which may also be known as the electromagnetic transfer function of the haptic transducer. In an ideal case, magnetic force factor Bl can be given by the product B·l, where B is magnetic flux density and l is a total length of electrical conductor within a magnetic field. Both magnetic flux density B and length l should remain constant in an ideal case with motion occurring along a single axis.

In generating haptic vibration, an LRA may undergo displacement. In order to protect an LRA from damage, such displacement may be limited. Accordingly, accurate measurement of displacement may be crucial in optimizing LRA displacement protection algorithms Accurate measurement of displacement may also enable increased drive levels of the LRA. While existing approaches measure displacement, such approaches have disadvantages. For example, displacement may be measured using a Hall sensor, but Hall sensors are often costly to implement.

### SUMMARY

In accordance with the teachings of the present disclosure, the disadvantages and problems associated with existing approaches for sensing displacement of an electromagnetic transducer may be reduced or eliminated.

In accordance with embodiments of the present disclosure, a system for detecting displacement of a movable member of an electromagnetic transducer having a magnetic coil-driven linear actuator with a static member and a movable mass mechanically coupled to the static member and having a back electromotive force present across terminals of a coil of the electromagnetic transducer is provided. The system may include a resistive-inductive-capacitive sensor comprising the coil, a driver configured to drive the resistive-inductive-capacitive sensor with a driving signal, a measurement circuit communicatively coupled to the resistive-inductive-capacitive sensor and configured to measure one or more of phase information and amplitude information associated with the resistive-inductive-capacitive sensor and based on the one or more of phase information and amplitude information, determine a displacement of movable mass, wherein the displacement of the movable mass causes a change in an impedance of the resistive-inductive-capacitive sensor.

In accordance with these and other embodiments of the present disclosure, a system for detecting displacement of a movable member of an electromagnetic transducer having a magnetic coil-driven linear actuator with a static member and a movable mass mechanically coupled to the static member and having a back electromotive force present across terminals of a coil of the electromagnetic transducer may be provided. The system may include a measurement circuit communicatively coupled to the coil and configured to monitor a voltage and a current associated with the coil, drive the electromagnetic transducer with a driving signal, based on the monitored voltage and current, estimate an impedance of the coil including a coil resistance and coil inductance of the linear actuator, and based on the coil inductance, determine a displacement of movable mass, wherein the displacement of the movable mass causes a change in an impedance of the linear actuator.

In accordance with these and other embodiments of the present disclosure, a method for detecting displacement of a movable member of an electromagnetic transducer having a magnetic coil-driven linear actuator with a static member and a movable mass mechanically coupled to the static member and having a back electromotive force present across terminals of a coil of the electromagnetic transducer is provided. The method may include driving a resistive-inductive-capacitive sensor comprising the coil with a driving signal, measuring one or more of phase information and amplitude information associated with the resistive-inductive-capacitive sensor, and based on the one or more of phase information and amplitude information, determining a displacement of movable mass, wherein the displacement of the movable mass causes a change in an impedance of the resistive-inductive-capacitive sensor.

In accordance with these and other embodiments of the present disclosure, a method for detecting displacement of a movable member of an electromagnetic transducer having a magnetic coil-driven linear actuator with a static member and a movable mass mechanically coupled to the static member and having a back electromotive force present across terminals of a coil of the electromagnetic transducer is provided. The method may include monitoring a voltage and a current associated with the coil, driving the electromagnetic transducer with a driving signal, based on the monitored voltage and current, estimating an impedance of the coil including a coil resistance and coil inductance of the linear actuator, and based on the coil inductance, determining a displacement of movable mass, wherein the displacement of the movable mass causes a change in an impedance of the linear actuator.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an example of a vibro-haptic system in a device, as is known in the art;

FIG. 2 illustrates an example of a Linear Resonant Actuator (LRA) modelled as a linear system, as is known in the art;

FIG. 3 illustrates selected components of an example host device, in accordance with embodiments of the present disclosure; and

Each of FIGS. 4A-4C illustrates a diagram of selected components of an example resonant phase sensing system, in accordance with embodiments of the present disclosure.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiment discussed below, and all such equivalents should be deemed as being encompassed by the present disclosure.

Various electronic devices or smart devices may have transducers, speakers, and acoustic output transducers, for example any transducer for converting a suitable electrical driving signal into an acoustic output such as a sonic pressure wave or mechanical vibration. For example, many electronic devices may include one or more speakers or loudspeakers for sound generation, for example, for playback of audio content, voice communications and/or for providing audible notifications.

Such speakers or loudspeakers may comprise an electromagnetic actuator, for example a voice coil motor, which is mechanically coupled to a flexible diaphragm, for example a conventional loudspeaker cone, or which is mechanically coupled to a surface of a device, for example the glass screen of a mobile device. Some electronic devices may also include acoustic output transducers capable of generating ultrasonic waves, for example for use in proximity detection-type applications and/or machine-to-machine communication.

Many electronic devices may additionally or alternatively include more specialized acoustic output transducers, for example, haptic transducers, tailored for generating vibrations for haptic control feedback or notifications to a user. Additionally or alternatively, an electronic device may have a connector, e.g., a socket, for making a removable mating connection with a corresponding connector of an accessory apparatus, and may be arranged to provide a driving signal to the connector so as to drive a transducer, of one or more of the types mentioned above, of the accessory apparatus when connected. Such an electronic device will thus comprise driving circuitry for driving the transducer of the host device or connected accessory with a suitable driving signal. For acoustic or haptic transducers, the driving signal may generally be an analog time varying voltage signal, for example, a time varying waveform.

To accurately sense displacement of an electromagnetic load, methods and systems of the present disclosure may determine an inductance of the electromagnetic load, and then convert the inductance to a position signal, as described in greater detail below. Further, to measure inductance of an electromagnetic load, methods and systems of the present disclosure may utilize either a phase measurement approach and/or a high-frequency pilot-tone driven approach, as also described in greater detail below.

To illustrate, an electromagnetic load may be driven by a driving signal V(t) to generate a sensed terminal voltage V_{T}(t) across a coil of the electromagnetic load. Sensed terminal voltage V_{T}(t) may be given by:

V_{T}(t)+V_{COIL}I(t)+V_{B}(t)

wherein I(t) is a sensed current through the electromagnetic load, Z_{COIL}, is an impedance of the electromagnetic load, and V_{B}(t) is the back-electromotive force (back-EMF) associated with the electromagnetic load.

As used herein, to “drive” an electromagnetic load means to generate and communicate a driving signal to the electromagnetic load to cause displacement of a movable mass of the electromagnetic load.

Because back-EMF voltage V_{B}(t) may be proportional to velocity of the moving mass of the electromagnetic load, back-EMF voltage V_{B}(t) may in turn provide an estimate of such velocity. Thus, velocity of the moving mass may be recovered from sensed terminal voltage V_{T}(t) and sensed current I(t) provided that either: (a) sensed current I(t) is equal to zero, in which case V_{B}=V_{T}; or (b) coil impedance Z_{COIL} is known or is accurately estimated.

Position of the moving mass may be related to a coil inductance L_{COIL} of the electromagnetic load. At high frequencies significantly above the bandwidth of the electromagnetic load, back-EMF voltage V_{B}(t) may become negligible and inductance may dominate the coil impedance Z_{COIL}. Sensed terminal voltage V_{T@HF}(t) at high frequencies may be estimated by:

V_{T@HF}(t)=Z_{COIL}I_{@HF}(t)

Hence, at high frequencies, the position of the moving mass of the electromagnetic load may be recovered from sensed terminal voltage V_{T}(t) and sensed current I(t) by: (a) estimating the coil impedance at high frequency as Z_{COIL@HF}≅R_{@HF}+L_{@HF}·S, where R_{@HF} is the resistive part of the coil impedance at high frequency, L_{@HF} is the coil inductance at high frequency, and s is the Laplace transform; and (b) converting the measured inductance to a position signal. Velocity and/or position may be used to control vibration of the moving mass of the electromagnetic load.

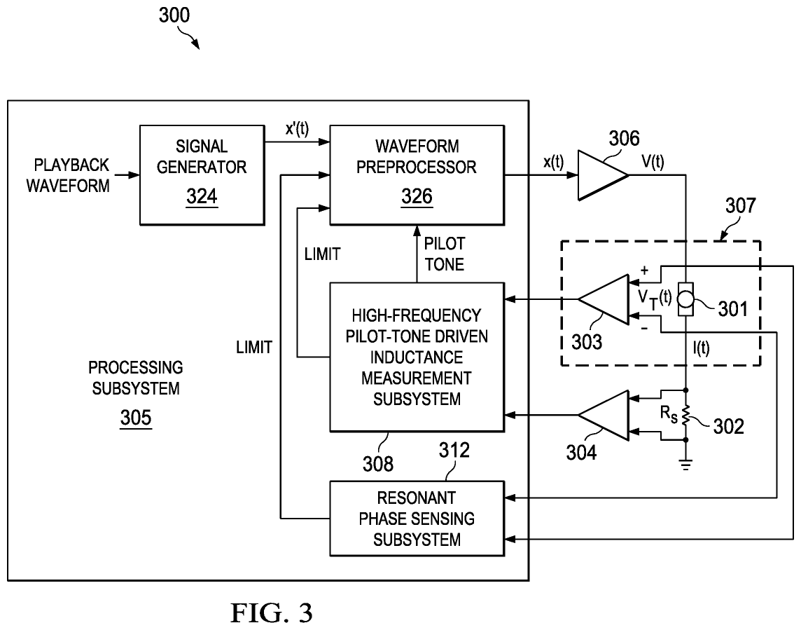

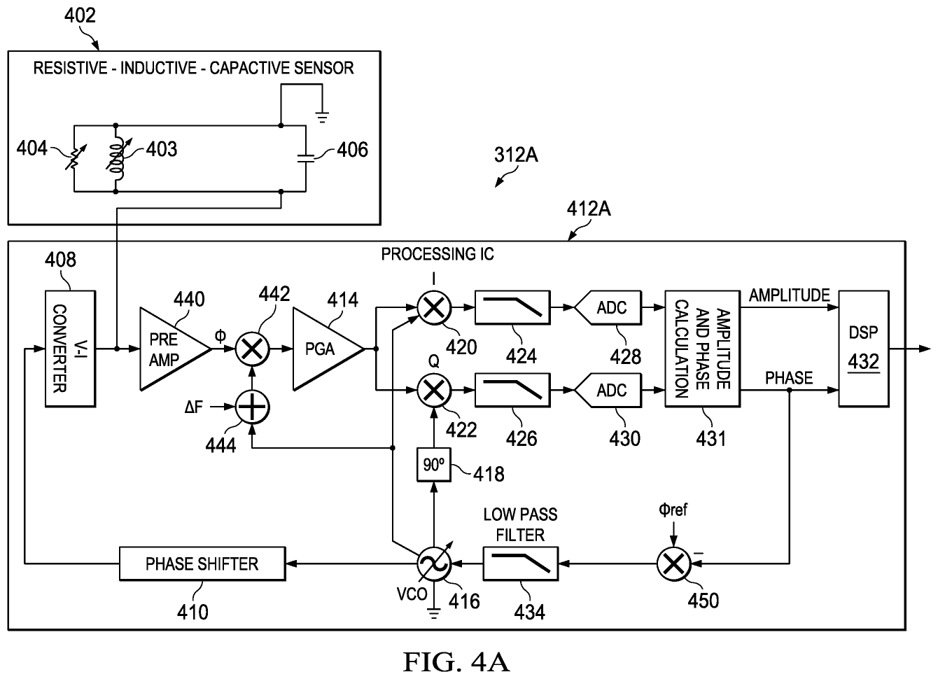

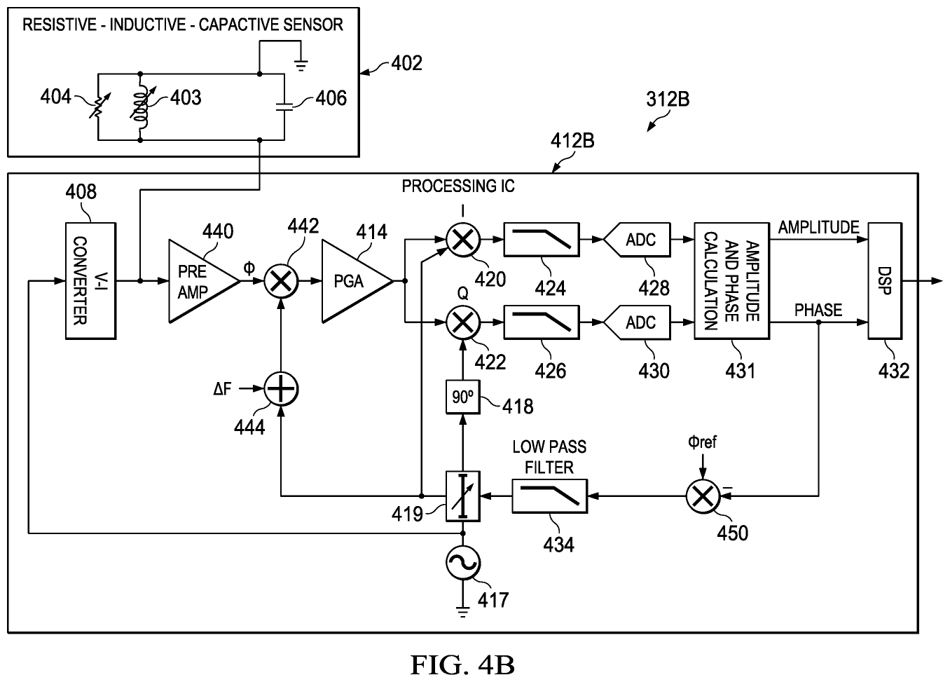

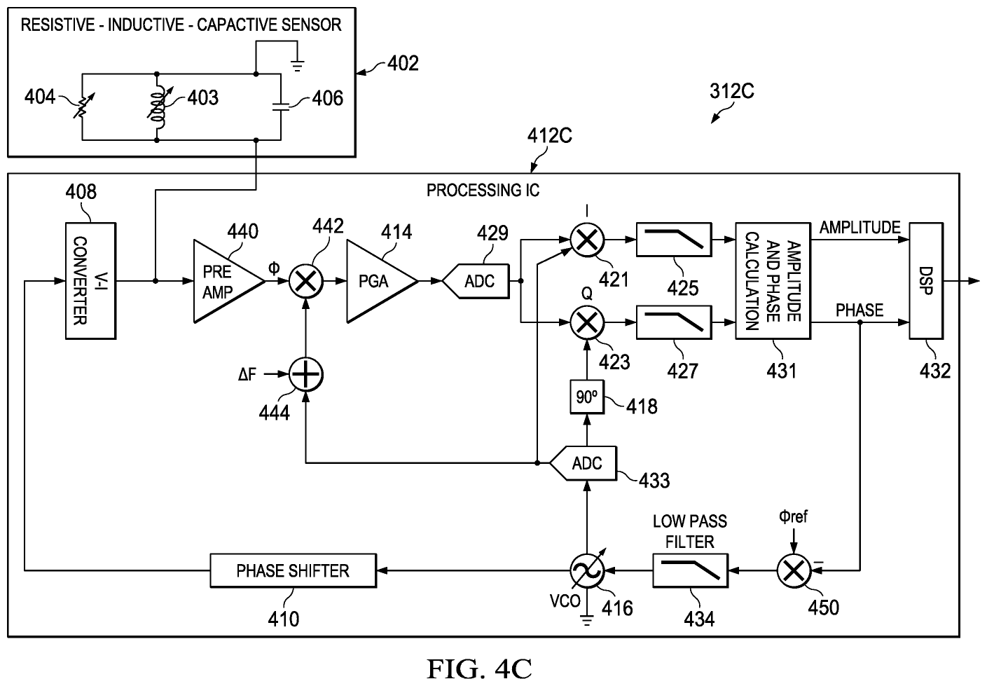

FIG. 3 illustrates selected components of an example host device 300 having an electromagnetic load 301, in accordance with embodiments of the present disclosure. Host device 300 may include, without limitation, a mobile device, home application, vehicle, and/or any other system, device, or apparatus that includes a human-machine interface. Electromagnetic load 301 may include any suitable load with a complex impedance, including without limitation a haptic transducer, a loudspeaker, a microspeaker, a piezoelectric transducer, a voice-coil actuator, a solenoid, or other suitable transducer.

In operation, a signal generator 324 of a processing subsystem 305 of host device 300 may generate a raw transducer driving signal x′(t) (which, in some embodiments, may be a waveform signal, such as a haptic waveform signal or audio signal). Raw transducer driving signal x′(t) may be generated based on a desired playback waveform received by signal generator 324.

Raw transducer driving signal x′(t) may be received by waveform preprocessor 326 which, as described in greater detail below, may modify raw transducer driving signal x′(t) based on a pilot tone generated by high-frequency pilot-tone driven inductance measurement subsystem 308, a limiting signal generated by high-frequency pilot-tone driven inductance measurement subsystem 308, and/or a limiting signal generated by resonant phase sensing subsystem 312 in order to generate processed transducer driving signal x(t).

Processed transducer driving signal x(t) may in turn be amplified by amplifier 306 to generate a driving signal V(t) for driving electromagnetic load 301. Responsive to driving signal V(t), a sensed terminal voltage V_{T}(t) of electromagnetic load 301 may be sensed by a terminal voltage sensing block 307, for example a volt-meter, and converted to a digital representation by a first analog-to-digital converter (ADC) 303. Similarly, sensed current I(t) may be converted to a digital representation by a second ADC 304. Current I(t) may be sensed across a shunt resistor 302 having resistance Rₛ coupled to a terminal of electromagnetic load 301.

As shown in FIG. 3, processing subsystem 305 may include a high-frequency pilot-tone driven inductance measurement subsystem 308 that may estimate coil inductance L_{COIL} of electromagnetic load 301. From such estimated coil inductance L_{COIL}, high-frequency pilot-tone driven inductance measurement subsystem 308 may determine a displacement associated with electromagnetic load 301. If such displacement exceeds a threshold, high-frequency pilot-tone driven inductance measurement subsystem 308 may communicate a limiting signal (indicated by “LIMIT” in FIG. 3) to modify raw transducer driving signal x′(t) in a manner that prevents over-excursion in the displacement of electromagnetic load 301.

In operation, to estimate impedance Z_{COIL}, high-frequency pilot-tone driven inductance measurement subsystem 308 may drive a high-frequency pilot tone to waveform preprocessor 326, which may in turn drive the high-frequency pilot tone as processed transducer driving signal x(t) in lieu of raw transducer driving signal x′(t) or may drive the combination of the high-frequency pilot tone and of raw transducer driving signal x′(t) as processed transducer driving signal x(t). In this context, “high-frequency” may mean significantly above the bandwidth of electromagnetic load 301 such that the high-frequency pilot tone has negligible effect on mechanical vibration of electromagnetic transducer. For example, electromagnetic load 301 may have a mechanical bandwidth of approximately 100 Hz-200 Hz while the high-frequency pilot tone may be driven at 10 kHz-40 kHz. As mentioned above, at higher frequencies, back-EMF voltage V_{B}(t) may become negligible such that:

V_{T@HF}(t)=Z_{COIL}I_{@HF}(t)

By measuring both the amplitude and response of the high-frequency components of sensed terminal voltage V_{T@HF}(t) and sensed current I_{@HF}(t), high-frequency pilot-tone driven inductance measurement subsystem 308 may be able to determine the real and imaginary components of impedance Z_{COIL}, wherein the real component of impedance Z_{COIL} represents the resistive part R_{@HF} of the coil impedance and the imaginary component of impedance Z_{COIL} represents coil inductance L_{@HF}. Such coil inductance L_{@HF} at high frequency may provide a reasonable estimate of coil inductance L from which high-frequency pilot-tone driven inductance measurement subsystem 308 may derive a displacement of electromagnetic load 301. In some embodiments, to obtain a more accurate phase measurement, high-frequency pilot-tone driven inductance measurement subsystem 308 may determine phase information based on zero crossings of either or both of sensed terminal voltage V_{T@HF}(t) and sensed current I_{@HF}(t). In addition, the ratio of the rate of change of a signal-to-noise ratio of sensed terminal voltage V_{T@HF}(t) and sensed current I_{@HF}(t) may be much higher at zero crossings. Accordingly, high-frequency pilot-tone driven inductance measurement subsystem 308 may be configured to tradeoff measurement convergence time (e.g., which may dictate an available number of zero crossings) with signal-to-noise ratio (e.g., which may dictate the power consumption and physical area of high-frequency pilot-tone driven inductance measurement subsystem 308). A higher bandwidth for the inductive sensing operation of high-frequency pilot-tone driven inductance measurement subsystem 308 may affect both signal-to-noise ratio and available convergence time (e.g., higher bandwidths may lead to lower signal-to-noise ratio but lower settling time and more zero crossings).

In some embodiments, the voltage and current sensing components used by high-frequency pilot-tone driven inductance measurement subsystem 308 may be the same sensing components used by processing subsystem 305 or another subsystem of host device 300 to measurement back-EMF to determine a velocity of the moving mass of electromagnetic load 301. In other embodiments, the voltage and current sensing components used by high-frequency pilot-tone driven inductance measurement subsystem 308 may be additional sensing components other than those used by processing subsystem 305 or another subsystem of host device 300 to measurement back-EMF to determine a velocity of the moving mass of electromagnetic load 301.

The inductive sensing approach performed by high-frequency pilot-tone driven inductance measurement subsystem 308 may be implemented using either a time-domain approach or a frequency-domain approach. Further, although not shown in FIG. 3 for purposes of clarity and exposition, any time-domain approach may require one or more band-pass filters with a higher settling time in order to remove noise and any direct-current offset, which may reduce an available number of zero crossings for measurement. A frequency-domain approach may be made more immune to noise by limiting the observation window around the fundamental frequency, thus providing a wide-bandwidth system that may be able to operate at a lower signal-to-noise ratio.

As also shown in FIG. 3, processing subsystem 305 may include a resonant phase sensing subsystem 312 that may also estimate coil inductance L_{COIL} of electromagnetic load 301. Similarly, from such estimated coil inductance L_{COIL}, resonant phase sensing subsystem 312 may determine a displacement associated with electromagnetic load 301. If such displacement exceeds a threshold, resonant phase sensing subsystem 312 may communicate a limiting signal (indicated by “LIMIT” in FIG. 3) to modify raw transducer driving signal x′(t) in a manner that prevents over-excursion in the displacement of electromagnetic load 301.

Resonant phase sensing subsystem 312 may include any system, device, or apparatus configured to detect a displacement of the moving mass of electromagnetic load 301. As described in greater detail below, resonant phase sensing subsystem 312 may detect displacement of the moving mass of electromagnetic load 301 by performing resonant phase sensing of a resistive-inductive-capacitive sensor for which an impedance (e.g., inductance, capacitance, and/or resistance) of the resistive-inductive-capacitive sensor changes in response to displacement of the moving mass of electromagnetic load 301. Details of example resonant phase sensing subsystems 312 in accordance with embodiments of the present disclosure are depicted in greater detail below.

FIG. 4A illustrates a diagram of selected components of an example resonant phase sensing subsystem 312A, in accordance with embodiments of the present disclosure. In some embodiments, resonant phase sensing subsystem 312A may be used to implement resonant phase sensing subsystem 312 of FIG. 3. As shown in FIG. 4A, resonant phase sensing subsystem 312A may include a resistive-inductive-capacitive sensor 402 and a processing integrated circuit (IC) 412A.

As shown in FIG. 4A, resistive-inductive-capacitive sensor 402 may include inductive coil 403, a resistor 404, and capacitor 406. Inductive coil 403 may comprise a coil of electromagnetic load 301 having coil inductance L_{COIL}. Although shown in FIG. 4A to be arranged in parallel with one another, it is understood that inductive coil 403, resistor 404, and capacitor 406 may be arranged in any other suitable manner that allows resistive-inductive-capacitive sensor 402 to act as a resonant tank. For example, in some embodiments, inductive coil 403, resistor 404, and capacitor 406 may be arranged in series with one another. In some embodiments, resistor 404 may not be implemented with a stand-alone resistor, but may instead be implemented by a parasitic resistance of inductive coil 403, a parasitic resistance of capacitor 406, and/or any other suitable parasitic resistance. In these and other embodiments, capacitor 406 may be implemented as a stand-alone shunt capacitor or may be implemented by one or more capacitors already present in host device 300 for other purposes, such as filter capacitors for reducing radio-frequency interference, for example.

Processing IC 412A may be communicatively coupled to resistive-inductive-capacitive sensor 402 and may comprise any suitable system, device, or apparatus configured to implement a measurement circuit to measure phase information associated with resistive-inductive-capacitive sensor 402 and based on the phase information, determine a displacement of a moving mass of electromagnetic load 301. For example, processing IC 412A may measure phase information associated with resistive-inductive-capacitive sensor 402, and based on such phase information, determine a change in coil inductance L_{COIL}, which is indicative of a change in position of the moving mass of electromagnetic load 301.

As shown in FIG. 4A, processing IC 412A may include a phase shifter 410, a voltage-to-current converter 408, a preamplifier 440, an intermediate frequency mixer 442, a combiner 444, a programmable gain amplifier (PGA) 414, a voltage-controlled oscillator (VCO) 416, a phase shifter 418, an amplitude and phase calculation block 431, a DSP 432, a low-pass filter 434, and a combiner 450. Processing IC 412A may also include a coherent incident/quadrature detector implemented with an incident channel comprising a mixer 420, a low-pass filter 424, and an analog-to-digital converter (ADC) 428, and a quadrature channel comprising a mixer 422, a low-pass filter 426, and an ADC 430 such that processing IC 412A is configured to measure the phase information using the coherent incident/quadrature detector.

Phase shifter 410 may include any system, device, or apparatus configured to detect an oscillation signal generated by processing IC 412A (as explained in greater detail below) and phase shift such oscillation signal (e.g., by 45 degrees) such that at normal operating frequency of resonant phase sensing subsystem 312A, an incident component of a sensor signal ϕ generated by pre-amplifier 440 is approximately equal to a quadrature component of sensor signal ϕ, so as to provide common mode noise rejection by a phase detector implemented by processing IC 412A, as described in greater detail below.

Voltage-to-current converter 408 may receive the phase shifted oscillation signal from phase shifter 410, which may be a voltage signal, convert the voltage signal to a corresponding current signal, and drive the current signal on resistive-inductive-capacitive sensor 402 at a driving frequency with the phase-shifted oscillation signal in order to generate sensor signal ϕ which may be processed by processing IC 412A, as described in greater detail below. In some embodiments, a driving frequency of the phase-shifted oscillation signal may be selected based on a resonant frequency of resistive-inductive-capacitive sensor 402 (e.g., may be approximately equal to the resonant frequency of resistive-inductive-capacitive sensor 402).

Preamplifier 440 may receive sensor signal ϕ and condition sensor signal ϕ for frequency mixing, with mixer 442, to an intermediate frequency Δf combined by combiner 444 with an oscillation frequency generated by VCO 416, as described in greater detail below, wherein intermediate frequency Δf is significantly less than the oscillation frequency. In some embodiments, preamplifier 440, mixer 442, and combiner 444 may not be present, in which case PGA 414 may receive sensor signal ϕ directly from resistive-inductive-capacitive sensor 402. However, when present, preamplifier 440, mixer 442, and combiner 444 may allow for mixing sensor signal ϕ down to a lower intermediate frequency Δf which may allow for lower-bandwidth and more efficient ADCs (e.g., ADCs 428 and 430 of FIGS. 4A and 4B and ADC 429 of FIG. 4C, described below) and/or which may allow for minimization of phase and/or gain mismatches in the incident and quadrature paths of the phase detector of processing IC 412A.

In operation, PGA 414 may further amplify sensor signal ϕ to condition sensor signal ϕ for processing by the coherent incident/quadrature detector. VCO 416 may generate an oscillation signal to be used as a basis for the signal driven by voltage-to-current converter 408, as well as the oscillation signals used by mixers 420 and 422 to extract incident and quadrature components of amplified sensor signal ϕ. As shown in FIG. 4A, mixer 420 of the incident channel may use an unshifted version of the oscillation signal generated by VCO 416, while mixer 422 of the quadrature channel may use a 90-degree shifted version of the oscillation signal phase shifted by phase shifter 418. As mentioned above, the oscillation frequency of the oscillation signal generated by VCO 416 may be selected based on a resonant frequency of resistive-inductive-capacitive sensor 402 (e.g., may be approximately equal to the resonant frequency of resistive-inductive-capacitive sensor 402).

In some embodiments, all or a portion of the driving circuitry (e.g., voltage-to-current converter 408, preamplifier 440, mixer 442, and/or PGA 414) may be implemented in whole or in part within waveform preprocessor 326 and/or amplifier 306, such that the driving signal provided for sensing of phase information may be the same as a haptic signal used to drive haptic effects at electromagnetic load 301.

In the incident channel, mixer 420 may extract the incident component of amplified sensor signal ϕ, low-pass filter 424 may filter out the oscillation signal mixed with the amplified sensor signal ϕ to generate a direct current (DC) incident component, and ADC 428 may convert such DC incident component into an equivalent incident component digital signal for processing by amplitude and phase calculation block 431. Similarly, in the quadrature channel, mixer 422 may extract the quadrature component of amplified sensor signal ϕ, low-pass filter 426 may filter out the phase-shifted oscillation signal mixed with the amplified sensor signal ϕ to generate a direct current (DC) quadrature component, and ADC 430 may convert such DC quadrature component into an equivalent quadrature component digital signal for processing by amplitude and phase calculation block 431.

Amplitude and phase calculation block 431 may include any system, device, or apparatus configured to receive phase information comprising the incident component digital signal and the quadrature component digital signal and based thereon, extract amplitude and phase information.

DSP 432 may include any system, device, or apparatus configured to interpret and/or execute program instructions and/or process data. In particular, DSP 432 may receive the phase information and the amplitude information generated by amplitude and phase calculation block 431 and based thereon, determine a displacement (or rather, a change in displacement) of the moving mass of electromagnetic load 301. DSP 432 may also generate an output signal indicative of the displacement. In some embodiments, such output signal may comprise a control signal for limiting a driving signal to electromagnetic load 301 (e.g., processed transducer driving signal x(t)) in response to the displacement (e.g., in response to the displacement exceeding a threshold value).

The phase information generated by amplitude and phase calculation block 431 may be subtracted from a reference phase ϕ_{ref} by combiner 450 in order to generate an error signal that may be received by low-pass filter 434. Low-pass filter 434 may low-pass filter the error signal, and such filtered error signal may be applied to VCO 416 to modify the frequency of the oscillation signal generated by VCO 416, in order to drive sensor signal ϕ towards reference phase ϕ_{ref}.

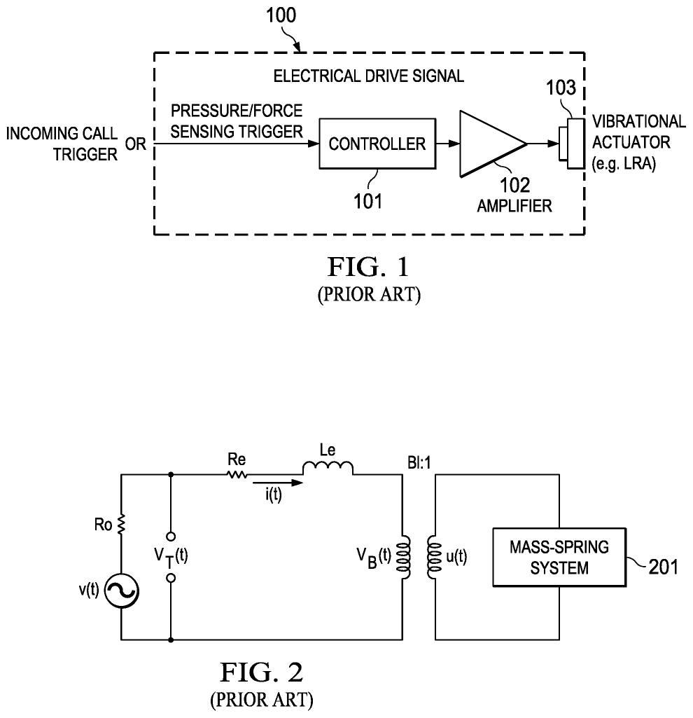

FIG. 4B illustrates a diagram of selected components of an example resonant phase sensing subsystem 312B, in accordance with embodiments of the present disclosure. In some embodiments, resonant phase sensing subsystem 312B may be used to implement resonant phase sensing subsystem 312 of FIG. 1. Resonant phase sensing subsystem 312B of FIG. 4B may be, in many respects, similar to resonant phase sensing subsystem 312A of FIG. 4A. Accordingly, only those differences between resonant phase sensing subsystem 312B and resonant phase sensing subsystem 312A may be described below. As shown FIG. 4B, resonant phase sensing subsystem 312B may include processing IC 412B in lieu of processing IC 412A. Processing IC 412B of FIG. 4B may be, in many respects, similar to processing IC 412A of FIG. 4A. Accordingly, only those differences between processing IC 412B and processing IC 412A may be described below.

Processing IC 412B may include fixed-frequency oscillator 417 and variable phase shifter 419 in lieu of VCO 416 of processing IC 412A. Thus, in operation, oscillator 417 may drive a fixed driving signal and oscillation signal which variable phase shifter 419 may phase shift to generate oscillation signals to be mixed by mixers 420 and 422. Similar to that of processing IC 412A, low-pass filter 434 may low-pass filter an error signal based on phase information extracted by amplitude and phase calculation block 431, but instead such filtered error signal may be applied to variable phase shifter 419 to modify the phase offset of the oscillation signal generated by oscillator 417, in order to drive sensor signal ϕ towards indicating a phase shift of zero.

FIG. 4C illustrates a diagram of selected components of an example resonant phase sensing subsystem 312C, in accordance with embodiments of the present disclosure. In some embodiments, resonant phase sensing subsystem 312C may be used to implement resonant phase sensing subsystem 312 of FIG. 1. Resonant phase sensing subsystem 312C of FIG. 4C may be, in many respects, similar to resonant phase sensing subsystem 312A of FIG. 4A. Accordingly, only those differences between resonant phase sensing subsystem 312C and resonant phase sensing subsystem 312A may be described below. For example, a particular difference between resonant phase sensing subsystem 312C and resonant phase sensing subsystem 312A is that resonant phase sensing subsystem 312C may include ADC 429 and ADC 433 in lieu of ADC 428 and ADC 430. Accordingly, a coherent incident/quadrature detector for resonant phase sensing subsystem 312C may be implemented with an incident channel comprising a digital mixer 421 and a digital low-pass filter 425 (in lieu of analog mixer 420 and analog low-pass filter 424) and a quadrature channel comprising a digital mixer 423 and a low-pass filter 427 (in lieu of analog mixer 422 and analog low-pass filter 426) such that processing IC 412C is configured to measure the phase information using such coherent incident/quadrature detector. Although not explicitly shown, resonant phase sensing subsystem 312B could be modified in a manner similar to that of how resonant phase sensing subsystem 312A is shown to be modified to result in resonant phase sensing subsystem 312C.

In some embodiments of processing subsystem 305, high-frequency pilot-tone driven inductance measurement subsystem 308 and resonant phase sensing subsystem 312 may operate in parallel and/or in tandem to determine coil inductance L_{COIL}, determine displacement of the moving mass of electromagnetic load 301, and/or limit processed transducer driving signal x(t). However, some embodiments of processing subsystem 305 may include only one of high-frequency pilot-tone driven inductance measurement subsystem 308 and resonant phase sensing subsystem 312.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system for detecting displacement of a movable member of an electromagnetic transducer having a magnetic coil-driven linear actuator with a static member and a movable mass mechanically coupled to the static member and having a back electromotive force present across terminals of a coil of the electromagnetic transducer, the system comprising:
a resistive-inductive-capacitive sensor comprising the coil;
a driver configured to drive the resistive-inductive-capacitive sensor with a driving signal;
a measurement circuit communicatively coupled to the resistive-inductive-capacitive sensor and configured to:
measure one or more of phase information and amplitude information associated with the resistive-inductive-capacitive sensor; and
based on the one or more of phase information and amplitude information, determine a displacement of movable mass, wherein the displacement of the movable mass causes a change in an impedance of the resistive-inductive-capacitive sensor.

2. The system of claim 1, the resistive-inductive-capacitive sensor comprising a shunt capacitor coupled to the coil.

3. The system of claim 2, the resistive-inductive-capacitive sensor comprising a shunt capacitor coupled to the coil in parallel.

4. The system of claim 2, wherein the shunt capacitor comprises a capacitor coupled to a filter network.

5. The system of claim 1, wherein the linear actuator is a voice-coil actuator.

6. The system of claim 1, wherein the linear actuator is a solenoid.

7. The system of claim 1, wherein the driving signal is a haptic playback waveform.

8. A system for detecting displacement of a movable member of an electromagnetic transducer having a magnetic coil-driven linear actuator with a static member and a movable mass mechanically coupled to the static member and having a back electromotive force present across terminals of a coil of the electromagnetic transducer, the system comprising a measurement circuit communicatively coupled to the coil and configured to:
monitor a voltage and a current associated with the coil;
drive the electromagnetic transducer with a driving signal;
based on the monitored voltage and current, estimate an impedance of the coil including a coil resistance and coil inductance of the linear actuator; and
based on the coil inductance, determine a displacement of movable mass, wherein the displacement of the movable mass causes a change in an impedance of the linear actuator.

9. The system of claim 8, wherein the measurement circuit is further configured to:
drive a pilot signal to the linear actuator at a frequency significantly higher than the mechanical resonant bandwidth of the linear actuator;
monitor the voltage and the current responsive to the pilot signal; and
estimate the impedance based on the voltage and the current responsive to the pilot signal.

10. The system of claim 9, wherein the measurement circuit is further configured to drive the pilot signal simultaneously with a haptic playback waveform driven to the electromagnetic transducer.

11. The system of claim 8, wherein the linear actuator is a voice-coil actuator.

12. The system of claim 8, wherein the linear actuator is a solenoid.

13. A method for detecting displacement of a movable member of an electromagnetic transducer having a magnetic coil-driven linear actuator with a static member and a movable mass mechanically coupled to the static member and having a back electromotive force present across terminals of a coil of the electromagnetic transducer, the method comprising:
driving a resistive-inductive-capacitive sensor comprising the coil with a driving signal;
measuring one or more of phase information and amplitude information associated with the resistive-inductive-capacitive sensor; and
based on the one or more of phase information and amplitude information, determining a displacement of movable mass, wherein the displacement of the movable mass causes a change in an impedance of the resistive-inductive-capacitive sensor.

14. The method of claim 13, the resistive-inductive-capacitive sensor comprising a shunt capacitor coupled to the coil.

15. The method of claim 14, the resistive-inductive-capacitive sensor comprising a shunt capacitor coupled to the coil in parallel.

16. The method of claim 14, wherein the shunt capacitor comprises a capacitor coupled to a filter network.

17. The method of claim 13, wherein the linear actuator is a voice-coil actuator.

18. The method of claim 13, wherein the linear actuator is a solenoid.

19. The method of claim 13, wherein the driving signal is a haptic playback waveform.

20. A method for detecting displacement of a movable member of an electromagnetic transducer having a magnetic coil-driven linear actuator with a static member and a movable mass mechanically coupled to the static member and having a back electromotive force present across terminals of a coil of the electromagnetic transducer, the method comprising:
monitoring a voltage and a current associated with the coil;
driving the electromagnetic transducer with a driving signal;
based on the monitored voltage and current, estimating an impedance of the coil including a coil resistance and coil inductance of the linear actuator; and
based on the coil inductance, determining a displacement of movable mass, wherein the displacement of the movable mass causes a change in an impedance of the linear actuator.

21. The method of claim 20, further comprising:
driving a pilot signal to the linear actuator at a frequency significantly higher than the mechanical resonant bandwidth of the linear actuator;
monitoring the voltage and the current responsive to the pilot signal; and
estimating the impedance based on the voltage and the current responsive to the pilot signal.

22. The method of claim 21, further comprising driving the pilot signal simultaneously with a haptic playback waveform driven to the electromagnetic transducer.

23. The method of claim 20, wherein the linear actuator is a voice-coil actuator.

24. The method of claim 20, wherein the linear actuator is a solenoid.
